(19) United States
(12) Patent Application Publication
(10) Pub. No.: US 2022/0320813 A1
(43) Pub. Date: Oct. 6, 2022

(54) Optical Device

(71) Applicant: Nippon Telegraph and Telephone Corporation, Tokyo (JP)

(72) Inventors: Suguru Yamaoka, Tokyo (JP); Ryo Nakao, Tokyo (JP); Takaaki Kakitsuka, Tokyo (JP); Shinji Matsuo, Tokyo (JP)

(21) Appl. No.: 17/616,044

(22) PCT Filed: Jun. 5, 2019
(86) PCT No.: PCT/JP2019/022312

§ 371 Date: Dec. 2, 2021

(51) Int. Cl. H01S 3/063; H01S 3/16

(52) U.S. Cl. CPC H01S 3/0637; H01S 3/1628

(57) ABSTRACT

There are provided a first cladding layer formed on a Si substrate, a first core made of Si and formed on the first cladding layer, and a second cladding layer formed on the first cladding layer and covering the first core Additionally, this optical device includes a waveguide type laser formed over the second cladding layer, a second core made of InP and formed continuously to the laser, and a third cladding layer formed on the second cladding layer and covering the laser and the second core.

### CROSS-REFERENCE TO RELATED APPLICATIONS

This application is a national phase entry of PCT Application No. PCT/JP2019/022312, filed on Jun. 5, 2019, which application is hereby incorporated herein by reference.

### TECHNICAL FIELD

The present invention relates to optical devices, and more particularly to optical devices such as waveguide type semiconductor lasers.

### BACKGROUND

Si photonics is a technology that integrates an electronic circuit and an optical device which are made of Si on the same substrate by a CMOS technology. In this technology, an optical device that emits light is important, but the light emission efficiency of Si is very small because Si is an indirect transition semiconductor, and thus, it is difficult to utilize Si for the light emitting optical device.

III-V compound semiconductors, such as GaAs and InP, which are direct transition semiconductors and have high light emission efficiency, are typically used for light emitting optical devices. Thus, as an optical device applicable to the Si photonics, for example, a technology has been studied in which a III-V compound semiconductor is bonded to a Si substrate, and a laser structure (III-V on Si laser) is fabricated by using the bonded III-V compound semiconductor (see Non Patent Literature (NPL) 1). For such bonding between the silicon substrate and the III-V compound semiconductor, for example, well-known hydrophilic bonding or surface activated bonding is used.

An insulating film made of SiO₂ or the like is used at a bonding interface of the surface activated bonding or the hydrophilic bonding, and the substrate can be bonded through oxygen bonding at the bonding interface (NPL 1).

In a laser made of a III-V compound semiconductor and formed on a Si substrate, the refractive index of the Si substrate is higher than the refractive index of the upper cladding medium and is substantially the same as the refractive index of the active layer medium. Thus, in order to achieve high light confinement, it is necessary to design a distance between the active layer made of a III-V compound semiconductor and the Si substrate in several μm order so that a waveguide mode of the laser does not sense the refractive index of Si.

Incidentally, in the above-described laser structure, the thermal conductivity of SiO₂ is small, and thus, a problem arises in which heat generated in the active layer is not efficiently radiated to the Si substrate. The heat generation of the active layer has an effect of reducing light output and limiting a modulation rate, thereby deteriorating laser characteristics (NPL 2).

In order to solve the aforementioned problems regarding the light confinement and the heat radiation, it has been proposed to integrate a laser on a substrate having a lower refractive index and higher thermal conductivity than those of a core. For example, a laser structure using SiC having higher thermal conductivity and a lower refractive index than those of Si and InP for a substrate is expected to achieve high light output and high speed modulation because the heat radiation characteristics of the laser active layer can be improved and more current can be injected therein than that in the known structure.

The laser formed on the SiC substrate can be expected to have very excellent characteristics as a single optical device, while the use of the SiC substrate in the current structure makes application of the CMOS technology difficult. Thus, there is a challenge to achieve harmony with the Si photonics.

Citation List

Non Patent Literature

NPL 1: T. Fujii et al., “Epitaxial Growth of InP to Bury Directly Bonded Thin Active Layer on SiO2/Si Substrate for Fabricating Distributed Feedback Lasers on Silicon”, IET Optoelectron, vol. ₉, Iss. ₄, pp. 151-157, 2015.

NPL 2: W. Kobayashi et al., “50-Gb/s Direct Modulation of a 1.3-μm InGaAlAs-Based DFB Laser With a Ridge Waveguide Structure”, IEEE Journal of Selected Topics in Quantum Electronics, vol. 19, no. 4, 1500908, 2013.

### SUMMARY OF THE INVENTION

### Technical Problem

The laser described above is a laser structure on a SiC substrate having high thermal conductivity, and thus the thermal conductivity of a device increases. In this case, high light output and high speed modulation can be expected because a large amount of current can be injected into a semiconductor laser portion. However, mere use of SiC for the substrate does not facilitate adaptation of the laser to the Si photonics. In order to solve this problem, it is necessary to form a laser having the aforementioned configuration on a Si substrate or a Si layer, but such a structure has not been reported. Additionally, in order to couple a laser having the configuration described above to an optical device or electronic circuit made of Si, it is an important challenge to couple light emitted from the laser to a Si optical waveguide.

Embodiments of the present invention have been made to solve the problems described above, and an object of embodiments of the present invention is to optically couple a laser formed on a SiC layer and a Si optical waveguide to each other.

### Means for Solving the Problem

An optical device according to embodiments of the present invention includes a first cladding layer formed on a Si substrate, a first core made of Si and formed on the first cladding layer, a second cladding layer formed on the first cladding layer and covering the first core, a waveguide type laser formed over the second cladding layer and including an active layer composed of an InP-based compound semiconductor, a second core made of InP, formed continuously to the laser over the second cladding layer, and having a width decreasing as a distance from the laser increases, and a third cladding layer formed on the second cladding layer and covering the laser and the second core, in which a part of the first core is disposed so as to be able to optically be coupled to the second core, and the first cladding layer and the second cladding layer are composed of a material having higher thermal conductivity than thermal conductivity of InP.

In a configuration example of the optical device described above, the first cladding layer and the second cladding layer are composed of any of SiC, AlN, GaN, and diamond.

In a configuration example of the optical device, the third cladding layer is composed of SiO₂.

### Effects of Embodiments of the Invention

As described above, according to embodiments of the present invention, the second core made of InP, formed continuously to the laser, and having a width decreasing as the distance from the laser increases is disposed above the first core made of Si so as to be able to optically be coupled. Thus, the laser formed on the SiC layer and the Si optical waveguide can be optically coupled to each other.

### BRIEF DESCRIPTION OF THE DRAWINGS

FIG. 1A is a cross-sectional view illustrating a configuration of an optical device according to an embodiment of the present invention.

FIG. 1B is a plan view illustrating a partial configuration of the optical device according to the embodiment of the present invention.

FIG. 2A is a cross-sectional view illustrating a partial configuration of the optical device according to the embodiment of the present invention.

FIG. 2B is a cross-sectional view illustrating a partial configuration of the optical device according to the embodiment of the present invention.

FIG. 2C is a cross-sectional view illustrating a partial configuration of the optical device according to the embodiment of the present invention.

FIG. 2D is a cross-sectional view illustrating a partial configuration of the optical device according to the embodiment of the present invention.

FIG. 3 is a characteristic diagram illustrating a result of calculating a waveguide mode distribution of the optical device according to the embodiment.

FIG. 4A is computer graphics illustrating a result of calculating propagation of the waveguide mode of the optical device according to the embodiment.

FIG. 4B is computer graphics illustrating a result of calculating propagation of the waveguide mode of the optical device according to the embodiment.

### DETAILED DESCRIPTION OF ILLUSTRATIVE EMBODIMENTS

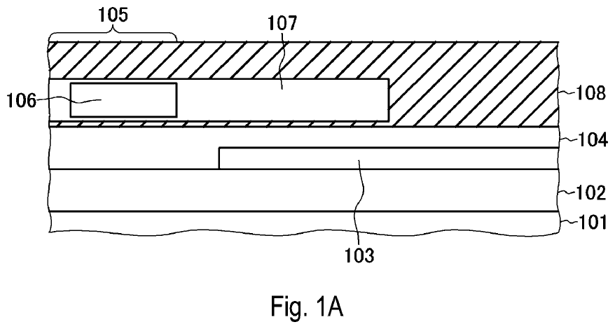

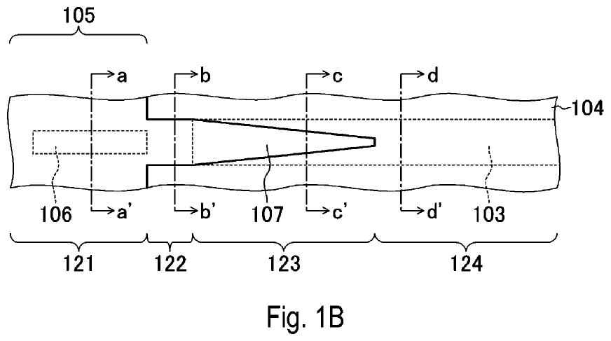

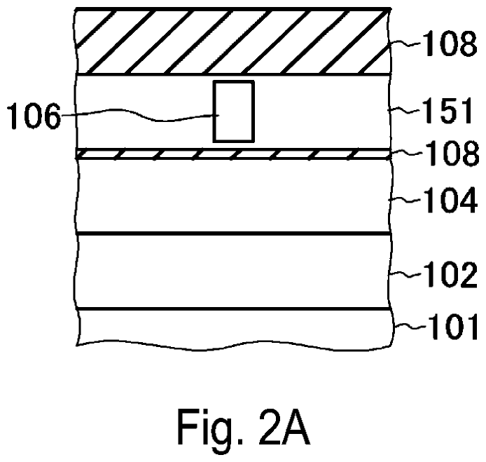

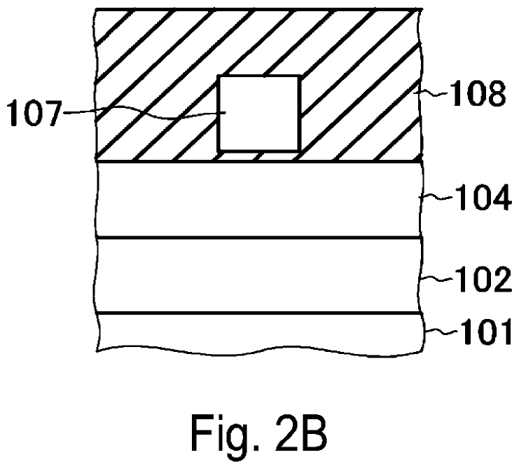

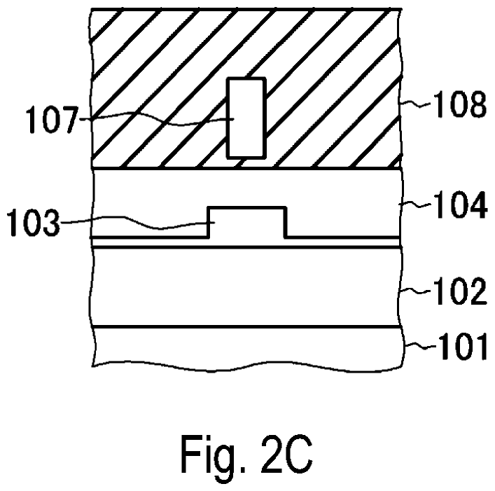

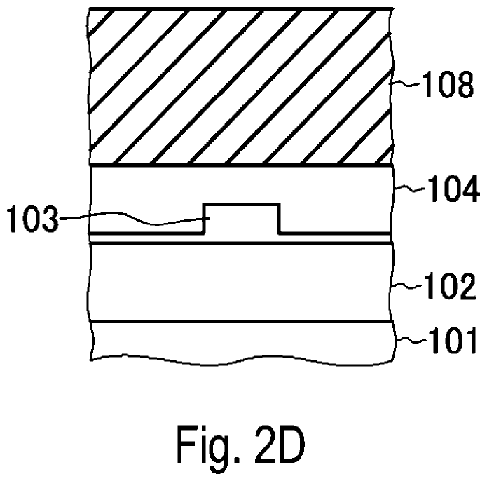

Hereinafter, an optical device according to an embodiment of the present invention will be described with reference to FIGS. 1A, 1B, 2A, 2B, 2C, and 2D. Note that FIG. 1A illustrates a cross section horizontal to a waveguide direction of the optical device. Note that FIG. 2A illustrates a cross section taken along the line a-a′ in FIG. 1B. FIG. 2B illustrates a cross section taken along the line b-b′ in FIG. 1B. FIG. 2C illustrates a cross section taken along the line c-c′ in FIG. 1B. FIG. 2D illustrates a cross section taken along the line d-d′ in FIG. 1B.

The optical device includes a first cladding layer 102 formed on a Si substrate 101, a first core 103 made of Si and formed on the first cladding layer 102, and a second cladding layer 104 formed on the first cladding layer 102 and covering the first core 103. In the embodiment, the first core 103 has a rib-type structure. Additionally, the optical device includes a waveguide type laser 105 formed over the second cladding layer 104, a second core 107 made of InP and formed continuously to the laser 105, and a third cladding layer 108 formed on the second cladding layer 104 and covering the laser 105 and the second core 107.

The Si substrate 101 is composed of single-crystal Si whose main surface has a plane orientation of (100). The first cladding layer 102 and the second cladding layer 104 are composed of a material having higher thermal conductivity than that of InP. For example, the first cladding layer 102 and the second cladding layer 104 can be composed of any of SiC, AlN, GaN, and diamond. These materials have a lower refractive index, higher thermal conductivity, and a larger band gap than those of any material that forms an active layer 106. For example, the first cladding layer 102 can be fabricated by lithographic etching or the like of a substrate composed of SiC, diamond, or the like, but a fabrication method is not limited thereto. Additionally, SiC can be deposited on the Si substrate 101. Additionally, the third cladding layer 108 is composed of, for example, SiO₂.

Additionally, the laser 105 includes the active layer 106 composed of an InP-based compound semiconductor. The second core 107 has a shape whose width decreases as the distance from the laser 105increases, in a plan view. Here, a part of the first core 103 is disposed so as to be able to optically be coupled to the second core 107. For example, a part of the first core 103 is disposed directly below the second core 107 on the side of the Si substrate 101. In this region, the part of the first core 103 is able to optically be coupled to the second core 107. Note that in the following, the side facing the Si substrate 101 is referred to as a lower side, and the side facing away from the Si substrate 101 is referred to as an upper side.

Note that for convenience of explanation, a region in which the laser 105 is formed is referred to as a first region 121. Additionally, a region of the optical waveguide configured of the second core 107 continuous to the laser 105 and uniform in width is referred to as a second region 122. Additionally, a region of the optical waveguide configured of a tapered portion where the width of the second core 107 gradually narrows is referred to as a third region 123. Additionally, a region where the second core 107 is not formed, but the optical waveguide configured of the first core 103 is provided is referred to as a fourth region 124.

In the optical waveguide structure configured in such a manner, first, light emitted from the laser 105 is optically coupled to the optical waveguide in the second region 122. In this manner, the light propagating in the optical waveguide in the second region 122 is guided with the mode system being widened at the tapered portion where the width of the second core 107 in the third region 123 gradually narrows. Additionally, the light described above is optically coupled to the optical waveguide configured of the first core 103 arranged under the tapered portion of the second core 107 in the third region 123, and its mode shifts to a waveguide mode of this optical waveguide. This is a well-known mode conversion structure.

The laser 105 will be described below in more detail. The active layer 106 has a multiple quantum well structure including a well layer and a barrier layer each of which is made of, for example, InGaAlAs, InGaAs, or InGaAsP having a different composition from each other. Alternatively, the active layer 106 may be composed of a compound semiconductor made of bulk InGaAlAs, InGaAs, InGaAsP, and the like. For example, a width of the active layer 106 can be set to 0.7 μm, and a thickness of the active layer 106 can be set to 0.32 μm. Note that the layer structure and the width are not limited thereto. The thickness of 0.32 μm of the active layer 106 is approximately the upper limit value at which light having a wavelength of 1.31 μm and propagating in the active layer 106 is in a single mode with respect to a thickness direction of the active layer 106. Additionally, although not illustrated, the laser 105 having the active layer 106 includes a distributed black Bragg reflection structure and a distributed feedback type resonant structure.

Additionally, the active layer 106 is embedded in a semiconductor layer 151 made of InP, for example. The semiconductor layer 151 at the upper side and the lower side of the active layer 106 is composed of non-doped InP. Additionally, the semiconductor layer 151 on the side of one side surface of the active layer 106 is composed of p-type InP, and the semiconductor layer 151 on the side of the other side surface of the active layer 106 is composed of n-type InP. A current injection structure into the active layer 106 is configured by using the p-i-n.

In the optical device described above, the active layer 106 and the second core 107 can be formed by a well-known crystal growth technique. Additionally, the second cladding layer 104 can be formed by a substrate bonding technique with the substrate where the active layer 106 is formed, but the fabrication method is not limited thereto. Additionally, in the embodiment, the light confinement in the horizontal direction of the substrate is achieved by a refractive index difference between the active layer 106 and the semiconductor layer 151, and a waveguide gain, but is not limited thereto, and any method of achieving light confinement, such as light confinement by using a two-dimensional photonic crystal structure, may be employed.

Incidentally, when the operating wavelength of the laser 105 and the material used for the active layer 106 are changed, in order for light to be in a single mode in the thickness direction of the active layer 106, a thickness t of the active layer 106 is only required to approximately satisfy the relationship of Expression (1) below when an operating wavelength is λ, an average refractive index of the active layer 106 is n_{core}, and a refractive index of the second cladding layer 104 is n_{clad}.

$$\begin{matrix}[ Math . 1 ] & \\ t < \frac{3}{2 π} \frac{λ}{\sqrt{{n}_{c o r e}^{2} - {n}_{clad}^{2}}} & ( 1 )\end{matrix}$$

For example, when light having a wavelength in a 1.55 μm band is used, the thickness t of the active layer 106 is equal to or smaller than 0.364 μm.

Next, a waveguide mode distribution of the optical device according to the embodiment will be described. Note that in the following, the first cladding layer 102 and the first core 103 were composed of SiC, the active layer 106 had a multiple quantum well structure including a well layer and a barrier layer each of which was made of InGaAlAs having a different composition from each other, the semiconductor layer 151 on the side of one side surface of the active layer 106 was made of p-type InP, and the semiconductor layer 151 on the side of the other side surface of the active layer 106 was made of n-type InP. Additionally, the second core 107 was made of InP.

Additionally, a width of the active layer 106 was set to 0.7 μm, a thickness thereof was set to 0.33 μm, a width of the second core 107 was set to 1.2 μm, and a thickness thereof was set to 0.33 μm. Additionally, the optical waveguide configured of the first core 103 had a rib-type structure, which had a rib width of 0.6 μm and a thickness of 0.2 μm. Additionally, the second core 107 was disposed over the first core 103 at a distance of 0.1 μm.

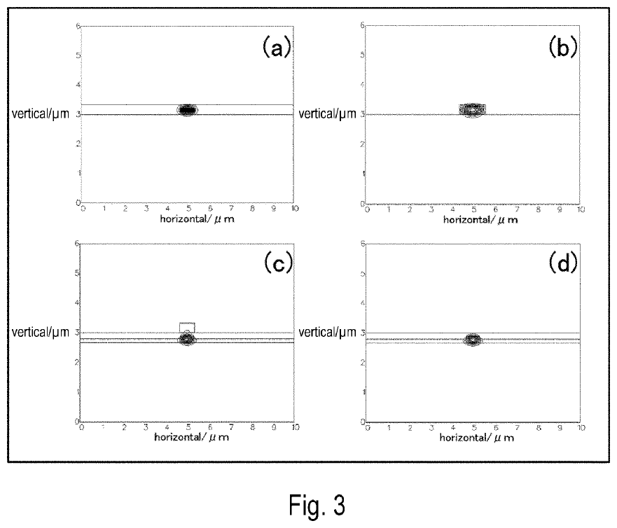

The waveguide mode distribution calculated based on the configuration described above is illustrated in FIG. 3. FIG. 3(a) illustrates the waveguide mode distribution in the first region 121 in the cross section illustrated in FIG. 2A. FIG. 3(b) illustrates the waveguide mode distribution in the second region 122 in the cross section illustrated in FIG. 2B. FIG. 3(c) illustrates the waveguide mode distribution in the third region 123 in the cross section illustrated in FIG. 2C. FIG. 3(d) illustrates the waveguide mode distribution in the fourth region 124 in the cross section illustrated in FIG. 2D. In FIG. 3, the waveguide mode distribution is illustrated by using contour lines.

As illustrated in FIG. 3(a), the waveguide mode in the first region 121 is a single mode. The width of 0.7 μm of the active layer 106 is approximately the upper limit value for single mode waveguiding. Next, as illustrated in FIG. 3(b), the waveguide mode is also a single mode in the optical waveguide in the second region 122. By setting the core width to 1.2 μm, the difference in equivalent refractive index between the portion of the laser 105 in the first region 121 and the optical waveguide configured of the second core 107 in the second region 122 becomes small, so an effect of reflection at the interface therebetween can be reduced. Note that, by designing the core width of the second core 107 in the second region 122 to be larger than 1.2 μm, the reflection is further suppressed, but in this case, multi-mode waveguiding is performed, which is not suitable for communication applications.

Next, as illustrated in (c) in FIG. 3, it can be seen that in the third region 123, inter-mode coupling occurs between the optical waveguide configured of the second core 107 and the optical waveguide configured of the first core 103. This is because the distance between the second core 107 and the first core 10 in the third region 123 is as close as approximately 100 nm. Next, as illustrated in (d) in FIG. 3, in the optical waveguide configured of the first core 103 in the fourth region 124, the waveguide mode is a single mode.

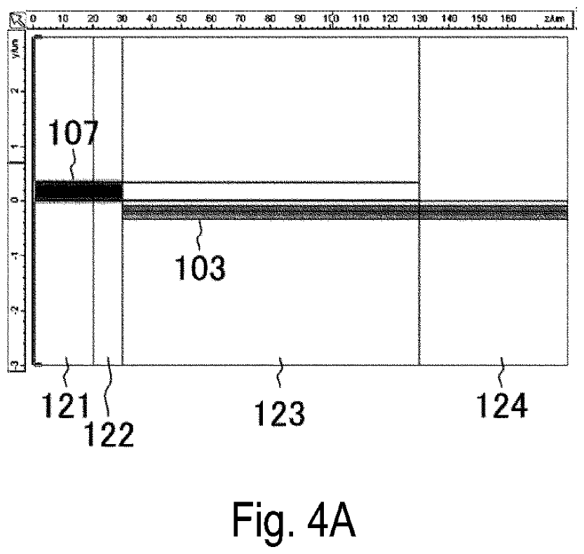

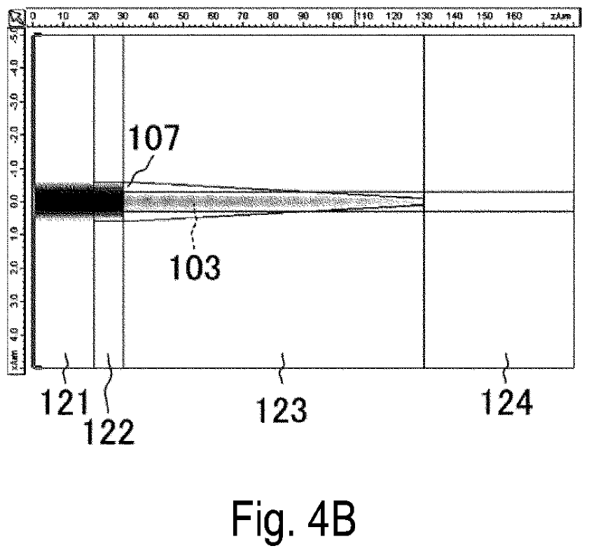

Next, a calculation result of propagation in the waveguide mode calculated based on the structure of the optical device according to the embodiment will be described with reference to FIGS. 4A and 4B. Note that FIG. 4A illustrates a state viewed from the side, and FIG. 4B illustrates a state viewed from the top. As illustrated in FIG. 4A, first, the waveguide mode formed in the first region 121 is coupled to the following optical waveguide configured of the second core 107 in the second region 122, and next, is coupled to the optical waveguide configured of the second core 107 in the third region 123. Next, as illustrated by the dark-colored portion in the figure, during propagation in the optical waveguide configured of the second core 107 in the third region 123, light is coupled to the optical waveguide configured of the first core 103, the waveguide mode is shifted, and the light is guided to the optical waveguide configured of the first core 103 in the fourth region 124.

Note that at the waveguide boundary from the first region 121 to the second region 122, an end surface of the connection portion is formed obliquely with respect to a plane orthogonal to a traveling direction of the light, which can reduce reflection of the light to the active layer 106 at the connection end surface. An inclination angle of the end surface of the connection portion of the first region 121 and the second region 122 with respect to the plane orthogonal to the traveling direction of the light is preferably approximately 7°, but is not limited to this angle. The calculation result illustrated in FIGS. 4A and 4B indicates that the light emitted from the laser 105 formed over the second cladding layer 104 made of SiC can be guided to the optical waveguide configured of the first core 103. This enables the semiconductor laser on SiC that can operate at high speed to be integrated with a modulation device and an electronic circuit which use Si, and thus the semiconductor laser on SiC can be adapted to the Si photonics.

As described above, according to the semiconductor optical device according to the embodiment of the present invention, it is possible to improve the characteristics of the semiconductor laser and to integrate the semiconductor laser with an optical device and an electronic circuit on Si at the same time. Note that in the above description, the Si substrate 101 is used, and high heat radiation can be obtained because the thermal conductivity of Si is relatively high such as approximately 130 times as large as that of SiO₂ and approximately ¼ times as large as that of SiC.

As described above, according to embodiments of the present invention, the second core made of InP, formed continuously to the laser, and having a width decreasing as the distance from the laser increases is disposed above the first core made of Si so as to be able to be optically coupled, which allows the laser formed on the SiC layer and the Si optical waveguide to be optically coupled to each other.

The present invention is not limited to the embodiment described above, and it is obvious that many modifications and combinations can be implemented by a person having ordinary knowledge in the field within the technical spirit of the present invention.

### Reference Signs List

101 Si substrate

102 First cladding layer

103 First core

104 Second cladding layer

106 Active layer

107 Second core

108 Third cladding layer

121 First region

122 Second region

123 Third region

124 Fourth region.

1-3. (canceled)

4. A optical device comprising:
a first cladding layer on a silicon substrate;
a first core made of silicon and on the first cladding layer;
a second cladding layer on the first cladding layer and covering the first core;
a waveguide type laser over the second cladding layer, the waveguide type laser including an active layer comprising an InP-based compound semiconductor;
a second core comprising InP extending continuously to the laser over the second cladding layer, the second core having a width decreasing as a distance from the laser increases; and
a third cladding layer on the second cladding layer and covering the laser and the second core, wherein a part of the first core is configured to be optically coupled to the second core, and wherein a material of the first cladding layer and a material of the second cladding layer each have a higher thermal conductivity than a thermal conductivity of InP.

5. The optical device according to claim 4, wherein
the material of the first cladding layer and the material of the second cladding layer each are SiC, AlN, GaN, or diamond.

6. The optical device according to claim 4, wherein
the third cladding layer is made of SiO₂.

7. A optical device comprising:
a first cladding layer on a substrate;
a first core on the first cladding layer;
a second cladding layer on the first cladding layer and covering the first core;
a waveguide type laser over the second cladding layer, the waveguide type laser including an active layer comprising a compound semiconductor;
a second core extending continuously to the laser over the second cladding layer, the second core having a width decreasing as a distance from the laser increases; and
a third cladding layer on the second cladding layer and covering the laser and the second core, wherein a material of the first cladding layer and a material of the second cladding layer each have a higher thermal conductivity than a thermal conductivity of a material of the second core.

8. The optical device of claim 7, wherein a material of the first core is silicon, and wherein the material of the second core is InP.

9. The optical device of claim 8, wherein the compound semiconductor is an InP-based compound semiconductor.

10. The optical device according to claim 8, wherein
the material of the first cladding layer and the material of the second cladding layer each are SiC, AlN, GaN, or diamond.

11. The optical device according to claim 7, wherein
the third cladding layer is made of SiO₂.

12. The optical device of claim 7, wherein the substrate is a silicon substrate.

13. The optical device of claim 7, wherein a part of the first core is configured to be optically be coupled to the second core.
